(19) United States
(12) Patent Application Publication
(10) Pub. No.: US 2024/0147862 A1
(43) Pub. Date: May 2, 2024

(54) METHOD FOR PRODUCING A MICROELECTROMECHANICAL OSCILLATION SYSTEM AND PIEZOELECTRIC MICROMACHINED ULTRASONIC TRANSDUCER

(71) Applicant: Robert Bosch GmbH, Stuttgart (DE)

(72) Inventors: Isabelle Raible, Tuebingen (DE); Jan David Brehm, Stuttgart (DE); Johannes Baader, Haslach (DE); Reinhold Roedel, Reutlingen (DE); Timo Schary, Aichtal-Neuenhaus (DE)

(21) Appl. No.: 18/547,915

(22) PCT Filed: Apr. 25, 2022
(86) PCT No.: PCT/EP2022/060909

§ 371 Date: Aug. 25, 2023

(30) Foreign Application Priority Data
May 28, 2021 (DE) 10 2021 205 486.2
Dec. 3, 2021 (DE) 10 2021 213 754.7

(51) Int. Cl. H10N 30/03; B06B 1/06

(52) U.S. Cl. CPC H10N 30/03; B06B 1/0644

(57) ABSTRACT

A method for producing a microelectromechanical oscillation system. A carrier substrate having a first surface is provided. A circumferential first trench is produced, which extends from the first surface at least partially through the carrier substrate. A passivation layer is applied to the first surface of the first carrier substrate and the first circumferential trench is at least partially filled with the passivation layer. A first polysilicon layer is grown on the passivation layer and/or the first surface of the carrier substrate. A transducer element of the microelectromechanical oscillation system is arranged on a second surface of the first polysilicon layer. A second trench is produced through the carrier substrate in the direction of the transducer element, which extends up to the passivation layer so that the oscillatable transducer plate of the microelectromechanical oscillation system is produced adjacent to the second trench using the first polysilicon layer.

### BACKGROUND INFORMATION

PCT Patent Application No. WO 2016 106153 describes a method for producing a piezoelectric micromachined ultrasonic transducer (pMUT), in which a passivation layer is deposited on a carrier substrate and subsequently patterned with the desired plate dimensions of the subsequently created transducer plate of the pMUT sensor. A polysilicon layer is subsequently deposited on the carrier substrate and/or the passivation layer, after which a transducer element is placed on its surface. Subsequently, a trench is created entirely through the carrier substrate until the polysilicon layer is reached by trenching.

However, in PCT Patent Application No. WO 2016 106153, the trench created has a comparatively wide and flat undercut towards the transducer element.

The present invention is based on the task of developing a method for producing a microelectromechanical oscillation system, which eliminates the aforementioned disadvantages of the related art.

### SUMMARY

A method for producing a microelectromechanical oscillation system, in particular a piezoelectric micromachined ultrasonic transducer, is provided according to the present invention. In addition, a piezoelectric micromachined ultrasonic transducer is provided according to the present invention.

According to an example embodiment of the present invention, in the method of producing a microelectromechanical oscillation system, a carrier substrate having a first surface is first provided. In particular, the carrier substrate is a silicon substrate and the microelectromechanical oscillation system is a piezoelectric micromachined ultrasonic transducer. Furthermore, a circumferential first trench is created. In this case, the first trench extends from the first surface of the carrier substrate at least partially through the carrier substrate, and an area of the first surface enclosed by the circumferential first trench has a defined shape and size. When referring to the defined shape and the defined size, it is preferably a shape and a size, in particular a length, of the transducer plate to be created in a plan view. Furthermore, a passivation layer is applied to the first surface of the first carrier substrate and, in this process, the first circumferential trench is at least partially filled with the passivation layer. Subsequently, a first polysilicon layer grows onto the passivation layer and/or the first surface of the carrier substrate. In particular, the first polysilicon layer grows epitaxially onto the passivation layer and/or the first surface of the carrier substrate. Additionally, a transducer element of the microelectromechanical oscillation system is arranged on a second surface of the first polysilicon layer. The transducer element is in particular a piezo element. In particular, the second surface is essentially oriented parallel to the first surface of the first carrier substrate. Furthermore, a second trench is created entirely through the carrier substrate in the direction of the transducer element. In this case, the second trench extends to the passivation layer, so that the oscillatable transducer plate of the microelectromechanical oscillation system is created adjacent to the second trench by means of the first polysilicon layer. By way of the first trench at least partially filled with the second passivation layer, the method allows for a precise definition of the position and length of the transducer plate to be created. Preferably, in the step of applying the passivation layer, the first circumferential trench is sealed by the passivation layer in particular at an upper end of the first trench.

According to an example embodiment of the present invention, preferably, following the application of the passivation layer to the first surface of the carrier substrate, the passivation layer is partially removed by means of a first etching mask such that the passivation layer remains only on a partial area of the first surface, which is enclosed by the first circumferential first trench. In this case, the partial area has a shape and a surface, in particular in a plan view, which corresponds to the oscillatable transducer plate to be created. The second trench preferably extends to the partial area of the second passivation layer. Preferably, the area of the first surface enclosed by the circumferential first trench and the contiguous partial area of the passivation layer coincide. In other words, the opening of the first trench is located at an outer edge area of the partial area of the second passivation layer.

According to an example embodiment of the present invention, preferably, following the application of the passivation layer to the first surface of the carrier substrate, the passivation layer is circumferentially removed by means of a second etching mask such that a third circumferential trench is created. The third trench extends to the first surface of the carrier substrate. The third circumferential trench encloses the first circumferential trench. In a subsequent method step, the first polysilicon layer in the area of the third trench then grows onto the surface of the carrier substrate, thus filling the third trench. This third, filled trench can be used as a lateral stop for isotropic chemical removal of the passivation layer in further method steps. Thus, the transducer plate can be manufactured with even more accurate lateral dimensions. Preferably, the third trench has an inclined or at least partially rounded wall. This reduces or prevents local stress overloads on the transducer plate under load.

According to an example embodiment of the present invention, preferably, the step of creating the second trench first includes a trenching step in which a fourth opening of an associated fourth trench mask has an opening size that is smaller, in particular significantly smaller, than a size of an area of the transducer plate. In a subsequent isotropic silicon etching step, the second trench is enlarged, in particular until the passivation layer is reached. This method avoids undercuts or steps in the second trench in the area of the carrier substrate. Preferably, the first trenching step already runs until the passivation layer is reached on the first surface of the carrier substrate, and the second trench is widened in the following isotropic silicon etching step until the passivation layer is reached within the first circumferential trench. Alternatively, the first trenching step is preferably terminated before the passivation layer is reached on the first surface, and the second trench is extended and widened in the following isotropic silicon etching step until the passivation layer is reached. This avoids undercuts or steps in the second trench. Alternatively, at least a third trench and a fourth trench laterally offset from the third trench are preferably first created by means of a fifth trench mask, in particular an associated fifth trench mask. In a subsequent method step, isotropic silicon etching is used to combine the third and fourth trenches to form the second trench. This embodiment is advantageous because the smaller opening area allows the trench to run through the carrier substrate faster, with less mask waste, with steeper slopes, and also more homogeneously.

According to an example embodiment of the present invention, preferably, the first circumferential trench is created by means of trenching such that the first trench at a lower end of the first trench has a diameter, in particular a width, in a range from 5 μm to 50 μm. Preferably, the first trench at the lower end of the first trench has a diameter, in particular a width, in a range from 5 μm to 20 μm. Since the trench rate falls as the ratio of the depth of the first trench to the width of the first trench increases, this comparatively wide formation of the first trench allows for a comparatively deep first trench. In order to still enable closure of the first trench at the upper end of the first trench and application of the passivation layer to the wall of the trench, preferably in a method step following the creation of the first circumferential trench, a wall, in particular an outer wall, of the first circumferential trench and on a bottom surface of the first circumferential trench is coated with a second polysilicon layer or an epitaxial silicon layer. Subsequently, during the step of applying the passivation layer to the first surface of the carrier substrate, the first circumferential trench is at least partially filled with the passivation layer and the first trench is closed by means of the passivation layer. Alternatively, it is preferably provided that, during the step of applying the passivation layer, a wall, in particular an outer wall, of the first circumferential trench is coated with the passivation layer, and subsequently the first circumferential trench is at least partially filled with a second polysilicon layer or an epitaxial silicon layer, and the first trench is closed by means of the second polysilicon layer or the epitaxial silicon layer. Furthermore, alternatively, a grid mask is preferably used as a fourth trench mask to create the first circumferential trench. Many small grid openings add up to a large lateral mask opening, which allows for a deep trench. However, the individual grid openings are small enough to still be closable with technically feasible SiO thicknesses. Subsequently, during the step of applying the passivation layer to the first surface of the carrier substrate, the first circumferential trench is at least partially filled with the passivation layer and closed by means of the passivation layer. All these methods allow for a comparatively deep circumferential first trench and thus also a comparatively long area of the first trench, the dimensions of which, in particular the diameter, are laterally limited and thus determined by the first trench.

According to an example embodiment of the present invention, preferably, the second trench is created by means of trenching. In this case, at least a third trench and a fourth trench laterally offset from the third trench are first created by means of a fifth trench mask, in particular an associated fifth trench mask. In a subsequent method step, isotropic silicon etching is used to combine the third and fourth trenches to form the second trench.

According to an example embodiment of the present invention, preferably, the passivation layer serves as the etching stop layer. The passivation layer is preferably formed as silicon oxide layers.

According to an example embodiment of the present invention, preferably, following the creation of the first trench, the passivation layer is at least partially removed.

Another subject matter of the present invention is a piezoelectric micromachined ultrasonic transducer, which is preferably manufactured by means of the method described above. According to an example embodiment of the present invention, the piezoelectric micromachined ultrasonic transducer has a carrier substrate, a first polysilicon layer, a transducer element, and an oscillatable transducer plate. The carrier substrate has a first surface on which the first polysilicon layer is arranged. The first polysilicon layer has a second surface, wherein the second surface is, in particular, essentially oriented parallel to the first surface of the first carrier substrate. The transducer element is disposed on the second surface of the first polysilicon layer. The transducer element is preferably a piezo element of the piezoelectric micromachined ultrasonic transducer. A second trench extends entirely through the carrier substrate in the direction of the transducer element to the first polysilicon layer such that the oscillatable transducer plate is formed, particularly directly adjacent to the second trench. The second trench is funnel-shaped in the direction of the transducer element in an area adjacent to the transducer plate, with a slope in a range from +0.5° to −4°. A tapering of the funnel corresponds to a negative slope and a widening of the funnel corresponds to a positive slope in the direction of the transducer element.

According to an example embodiment of the present invention, preferably, the piezoelectric micromachined ultrasonic transducer has a passivation layer that at least partially separates the first surface of the carrier substrate and the first silicon layer.

According to an example embodiment of the present invention, preferably, the first trench has a main extension direction which is essentially oriented perpendicularly to the first surface of the first carrier substrate.

### BRIEF DESCRIPTION OF THE DRAWINGS

FIG. 1 shows a first embodiment of a method for producing a microelectromechanical oscillation system, according to the present invention.

FIG. 2 shows a second embodiment of a method for producing a microelectromechanical oscillation system, according to the present invention.

FIG. 3 shows a third embodiment of a method for producing a microelectromechanical oscillation system, according to the present invention.

FIG. 4 shows a fourth embodiment of a method for producing a microelectromechanical oscillation system, according to the present invention.

FIG. 5 shows a fifth embodiment of a method for producing a microelectromechanical oscillation system, according to the present invention.

FIGS. 6A to 6C show various embodiments of the created third trench, according to the present invention.

### DETAILED DESCRIPTION OF EXAMPLE EMBODIMENTS

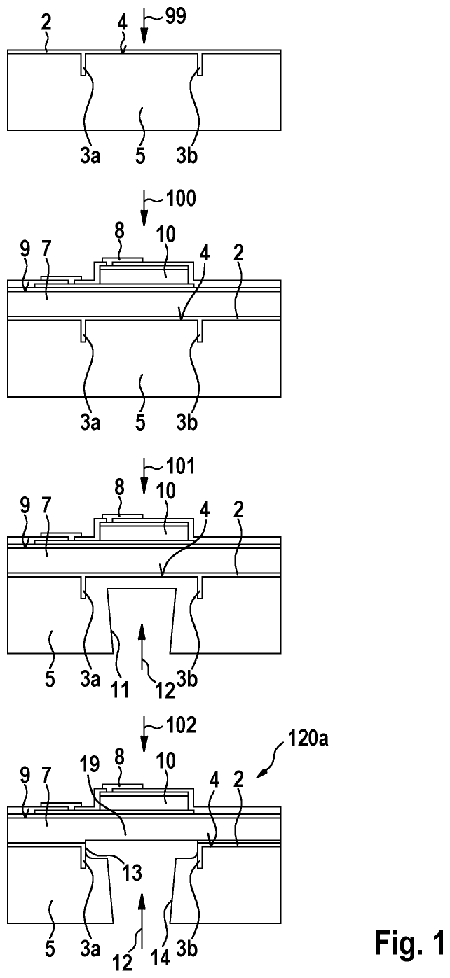

FIG. 1 schematically illustrates a first embodiment of a method for producing a microelectromechanical oscillation system in the form of a piezoelectric micromachined ultrasonic transducer 120a. Here, in a first method step 99, a carrier substrate 5 having a first surface 4 is provided. The carrier substrate 5 is designed as a silicon substrate. Furthermore, a first circumferential trench 3a and 3b is created. In this case, the first trench 3a and 3b extends from the first surface 4 of the carrier substrate 5 partially through the carrier substrate 5. An area of the first surface 4 enclosed by the circumferential first trench 3a and 3b here has a shape and a size of the oscillatable transducer plate 19 of the microelectromechanical oscillation system to be created later in a plan view. Moreover, a passivation layer 2 is applied to the first surface 4 of the first carrier substrate 5, and the first circumferential trench 3a and 3b is partially filled with the passivation layer 2 and an upper end of the first trench 3a and 3b is closed by means of the passivation layer. The passivation layer 2 serves as an etching stop layer and is formed, in this case, as a silicon oxide layer.

In a subsequent method step 100, a first polysilicon layer 7 grows onto the passivation layer 2. Furthermore, a piezo element is arranged as a transducer element 10 on a second surface 9 of the first polysilicon layer 7. Here, the second surface 9 is essentially oriented parallel to the first surface 4 of the first carrier substrate 5. In addition, the electrical contacting elements 8 of the piezo element are arranged on the first polysilicon layer 7.

In a following method step 101, a first trenching step for creating a second trench 14 is illustrated. For this trenching step, a third trench mask not shown here is used, which has a third opening with a size significantly smaller than a length of the transducer plate 19 to be created. In this case, the trenching step ends already before the passivation layer 2 is reached, leaving a third trench 11. In a subsequent method step 102, the third trench 11 is enlarged by means of a silicon etching step until the passivation layer 2 is reached, thus creating the second trench 14. The second trench 14 extends to the passivation layer 2, so that the oscillatable transducer plate 19 of the microelectromechanical oscillation system is created directly adjacent to the second trench 14 by means of the first polysilicon layer 7. Furthermore, the passivation layer in the area of the second trench 14 is removed.

The second trench has a main extension direction 12 that is essentially perpendicular to the first surface 4.

In a further method step not shown here, material of the carrier substrate 5 is additionally removed by means of a grinding process. Here, the material is removed such that, if possible, only the material of the carrier substrate originally enclosed by the first trench remains.

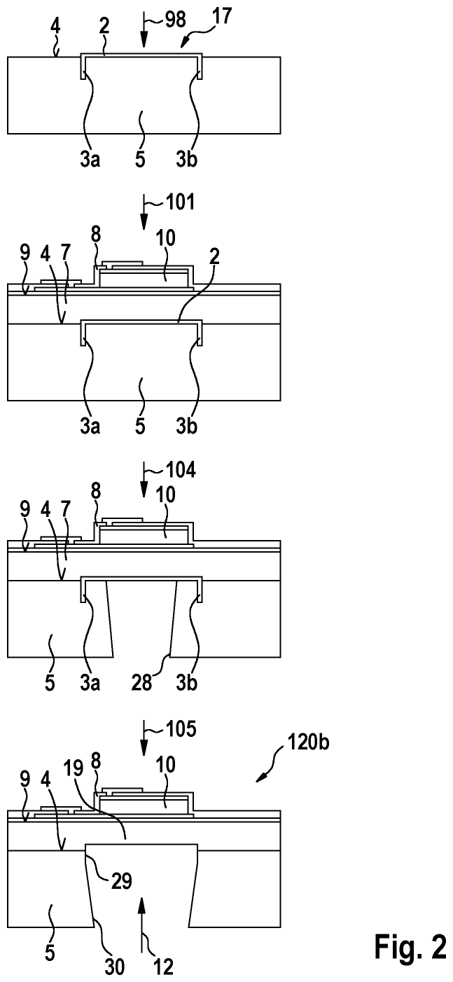

FIG. 2 schematically illustrates a second embodiment of a method for producing a microelectromechanical oscillation system in the form of a piezoelectric micromachined ultrasonic transducer 120b. In this case, in contrast to the embodiment shown in FIG. 1, in a method step 98 following the application of the passivation layer 2 to the first surface 4 of the carrier substrate 5, the passivation layer 2 is partially removed by means of a first etching mask, not shown here, such that the passivation layer 2 remains only on a partial area 17 of the first surface 4. The partial area 17 is enclosed by the first trench 3a and 3b.

In a method step 104 following the method step 101, a fifth trench 28 is created in a first trenching step to create a second trench 30 until the passivation layer 2 is reached. Again, the trench mask, which is not illustrated, has an opening that is significantly smaller than the area enclosed by the first trench 3a and 3b. It is only in a method step 105 following method step 104 that the fifth trench 28 is widened by means of a silicon etching step until it reaches the passivation layer 2 arranged within the first trench 3a and 3b. Subsequently, the passivation layer 2 is removed within the second trench 30.

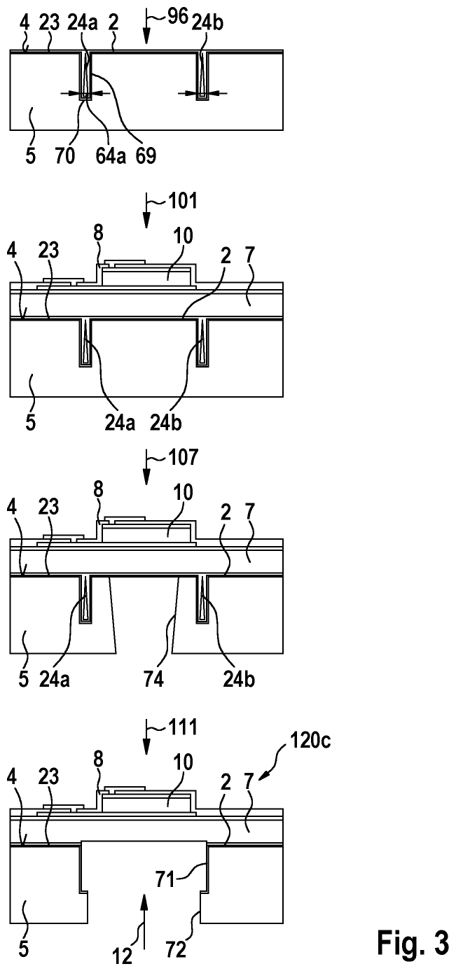

FIG. 3 schematically illustrates a third embodiment of a method for producing a microelectromechanical oscillation system in the form of a piezoelectric micromachined ultrasonic transducer 120c. In this case, in contrast to the above-described embodiments, in a method step 96 the first circumferential trench 24a and 24b is created by means of trenching such that the first trench 24a and 24b is comparatively wide with a diameter 64a and 64b. An outer wall and a bottom surface of the thus relatively wide and deep first trench 24a and 24b are subsequently coated with a second polysilicon layer 23. Subsequently, during the step of applying the passivation layer 2, the first circumferential trench 24a and 24b is partially filled with said passivation layer 2 and closed at an upper end of the first trench 24a and 24b by means of the passivation layer 2. In the illustrated embodiment, a reverse closure sequence of the first trench 24a and 24b would also be possible. In this case, the first trench 24a and 24a or an outer wall of the first trench 24a and 24b would first be coated with the passivation layer 2, and then the first trench 24a and 24b would be partially filled and sealed with the second polysilicon layer 23.

In a method step 107 following method step 101, a seventh trench 74 is initially created with a relatively narrow trench mask not shown here until the passivation layer 2 is reached. In a method step 111 following the method step 107, the seventh trench 74 is then widened until it reaches the passivation layer 2 disposed within the first trench 24a and 24b, thereby creating the second trench 72.

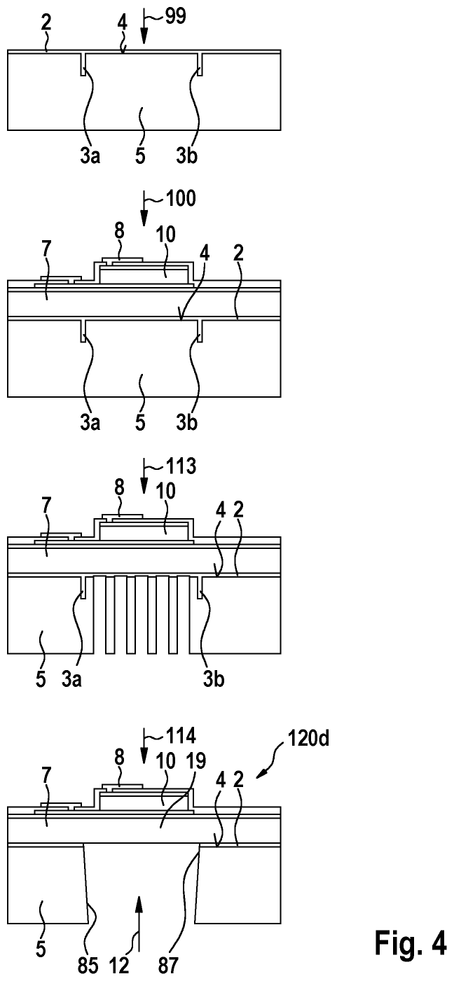

FIG. 4 schematically illustrates a fourth embodiment of a method for producing a microelectromechanical oscillation system in the form of a piezoelectric micromachined ultrasonic transducer 120d. In this case, in contrast to the above-described embodiments, in a method step 113 following method step 101, a plurality of relatively narrow trenches 84, laterally offset with respect to one another, are created in the carrier substrate 5 by means of a fifth trench mask not shown here. In a method step 114 following method step 113, isotropic silicon etching is used to enlarge the plurality of narrow trenches 84 to form the second trench 85. Subsequently, the passivation layer 4 is removed within the second trench 85.

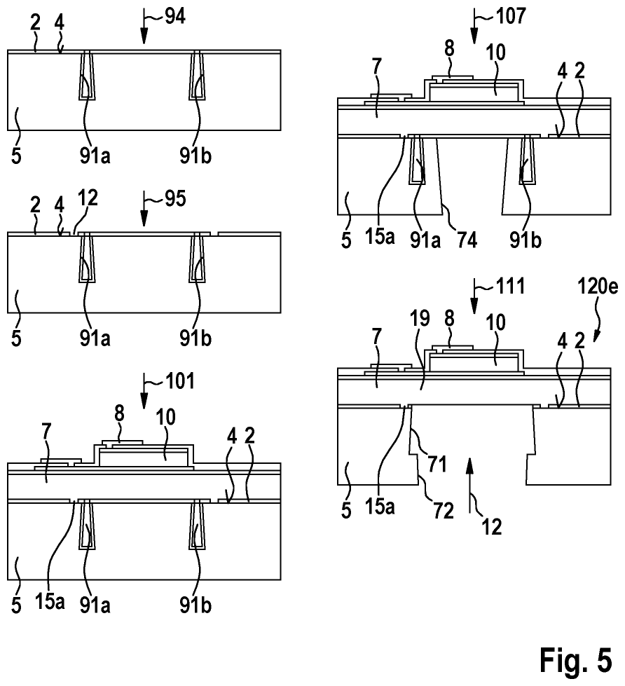

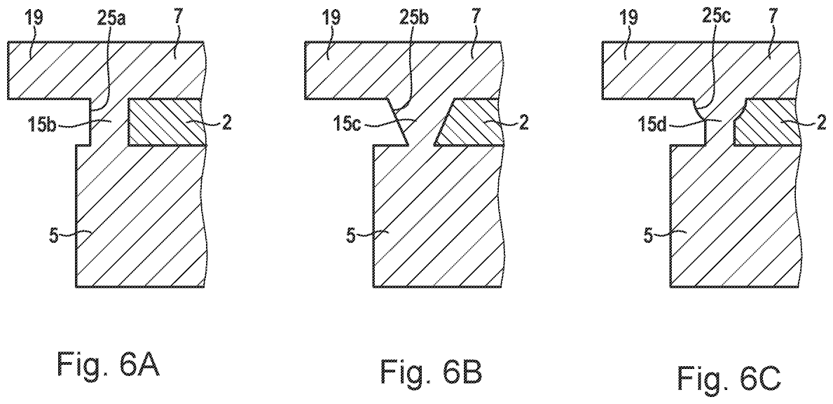

FIG. 5 schematically illustrates a fifth embodiment of a method for producing a microelectromechanical oscillation system in the form of a piezoelectric micromachined ultrasonic transducer 120e. In this case, too, just as in the embodiment shown in FIG. 3, a circumferential first trench 91a and 91b is created such that the first trench 91a and 91b is comparatively wide. To create the first circumferential trench 91a and 91b, a grid mask not shown here is used as a fourth trench mask. Many small grid openings add up to a large lateral mask opening, which allows for a deep trench. During the step of applying the passivation layer 2 to the first surface 4 of the carrier substrate 5, the first circumferential trench 91a and 91b is partially filled with the passivation layer 2 and closed by the passivation layer 2. In a method step 95 following method step 94, the passivation layer 2 is removed circumferentially by means of a second etching mask not shown here such that a third circumferential trench 12 is created. In this case, the third trench 12 extends to the first surface 4 of the carrier substrate 5 and surrounds the first circumferential trench 91a and 91b. In method step 101, the first polysilicon layer 7 grows onto the surface 4 of the carrier substrate 5 in the area of the third trench 12, thus filling the third trench 12. In method step 111, this third filled trench 15a serves as a lateral stop for the isotropic chemical removal of passivation layer 2. In this context, FIG. 6A illustrates a first embodiment of a third trench 15b filled with the first polysilicon layer 7 after the etching step 111 has been performed. In this case, the third trench 15b has a wall 25a that is perpendicular to the transducer plate 19. In contrast, the third trench 15c shown in FIG. 6B has a sloping wall 25b. This avoids stress overloads, which can lead to cracks when subjected to a load. Furthermore, 6C shows a third trench 15d with a partially rounded wall 25c. This gradual transition also prevents stress overloads when the load is high.

1-15 (canceled).

16. A method for producing a microelectromechanical oscillation system including a piezoelectric micromachined ultrasonic transducer, the method comprising the following steps:
providing a carrier substrate having a first surface;
creating a circumferential first trench, wherein the circumferential first trench extends from the first surface of the carrier substrate at least partially through the carrier substrate, wherein an area of the first surface enclosed by the circumferential first trench has a defined shape and a size an oscillatable transducer plate of the microelectromechanical oscillation system to be created in a plan view;
applying a passivation layer to the first surface of the first carrier substrate, wherein the first circumferential trench is at least partially filled with the passivation layer;
epitaxially growing a first polysilicon layer onto the passivation layer and/or the first surface of the carrier substrate;
arranging a transducer element of the microelectromechanical oscillation system, including a piezo element of the piezoelectric micromachined ultrasonic transducer, on a second surface of the first polysilicon layer, wherein the second surface is oriented parallel to the first surface of the first carrier substrate; and
creating a second trench entirely through the carrier substrate in a direction of the transducer element, wherein the second trench extends up to the passivation layer, so that the oscillatable transducer plate of the microelectromechanical oscillation system is created adjacent to the second trench using the first polysilicon layer.

17. The method according to claim 16, wherein the first circumferential trench is closed by the passivation layer, during the step of applying the passivation layer, at an upper end of the circumferential first trench.

18. The method according to claim 16, wherein following the application of the passivation layer to the first surface of the carrier substrate, the passivation layer is partially removed using a first etching mask such that the passivation layer remains only on a partial area of the first surface which is enclosed by the circumferential first trench.

19. The method according to claim 16, wherein following the application of the passivation layer to the first surface of the carrier substrate, the passivation layer is circumferentially removed using a second etching mask such that a third circumferential trench is created, wherein the third circumferential trench extends to the first surface of the carrier substrate, wherein the third circumferential trench encloses the circumferential first trench.

20. The method according to claim 16, wherein in that in the step of creating the second trench, first a first trenching step is carried out in which a third opening of an associated third trench mask has a size which is smaller than a size of an area of the transducer plate, and wherein in a subsequent isotropic silicon etching step, the second trench is enlarged until the passivation layer is reached.

21. The method according to claim 20, wherein the first trenching step continues until the passivation layer is reached on the first surface.

22. The method according to claim 20, wherein the first trenching step is terminated before reaching the passivation layer on the first surface.

23. The method according to claim 16, wherein the second trench is created by trenching, wherein at least a third trench and a fourth trench laterally offset with respect to the third trench are first created using a fifth trench mask, wherein the third and the fourth trench are subsequently combined to form the second trench by isotropic silicon etching.

24. The method according to claim 16, wherein the circumferential first trench is created by trenching such that the circumferential first trench at a lower end of the first trench has a diameter in a range from 5 μm to 50 μm.

25. The method according to claim 24, wherein, following the creation of the circumferential first trench, an outer wall of the circumferential first trench and a bottom surface of the circumferential first trench is coated with a second polysilicon layer or an epitaxial silicon layer, and subsequently the circumferential first trench is at least partially filled with the passivation layer in the step of applying the passivation layer to the first surface of the carrier substrate.

26. The method according to claim 24, wherein, during the step of applying the passivation layer, an outer wall of the circumferential first trench is coated with the passivation layer, and subsequently the circumferential first trench is at least partially filled with a second polysilicon layer or an epitaxial silicon layer.

27. The method according to claim 24, wherein a grid mask is used as a fourth trench mask to create the first circumferential trench, wherein subsequently, the circumferential first trench is at least partially filled with the passivation layer during the step of applying the passivation layer to the first surface of the carrier substrate, and the circumferential first trench is closed by the passivation layer.

28. The method according to claim 16, wherein the passivation layer serves as an etching stop layer.

29. The method according to claim 16, wherein the passivation layer is a silicon oxide layer.

30. A piezoelectric micromachined ultrasonic transducer, comprising:
a carrier substrate made of silicon;
a first polysilicon layer;
a transducer element; and
an oscillatable transducer plate;
wherein the carrier substrate has a first surface on which the first polysilicon layer is arranged, wherein the first polysilicon layer has a second surface, wherein the second surface is oriented parallel to the first surface of the first carrier substrate, wherein the transducer element includes a piezo element and is arranged on the second surface of the first polysilicon layer, wherein a second trench extends entirely through the carrier substrate in a direction of the transducer element up to the first polysilicon layer such that the oscillatable transducer plate is directly adjacent to the second trench, wherein the second trench is funnel-shaped in a direction of the transducer element in an area adjacent to the transducer plate with a gradient in a range from +0.5° to −4°.
